(19) United States
(12) Patent Application Publication
(10) Pub. No.: US 2007/0158050 A1
(43) Pub. Date: Jul. 12, 2007

(54) Microchannel heat sink manufactured from graphite materials

(76) Inventors: Julian Norley, Chagrin Falls, OH (US); Prathib Skandakumaran, Cleveland, OH (US); Matthew George Getz, Medina, OH (US)

Correspondence Address: James R. Cartiglia;Roundabout Plaza, Suite 500, 1600 Division Street, Nashville, TN, 37203, US

(21) Appl. No.: 11/327,832

(22) Filed: Jan. 6, 2006

(51) Int. Cl. H05K 7/20

(52) U.S. Cl. 165/80.4; 165/170; 361/699; 29/890.039

(57) ABSTRACT

A microchannel heat sink is manufactured from graphite materials. A heat sink member has at least a first thermal contact surface for making thermal contact with an electronic device. The heat sink member is constructed of at least a first sheet of compressed particles of exfoliated graphite, the first sheet having two major surfaces. At least one of the major surfaces has a first plurality of microchannels formed therein for carrying coolant fluid. Said microchannels each have a length parallel to one of said major surfaces and have a cross section normal to said length. The cross-section has at least one dimension below about 1000 microns.

### TECHNICAL FIELD

The present invention relates to a microchannel heat sink manufactured from graphite materials. The heat sink provides an apparatus for cooling an electronic device such as a microprocessor. The heat sink is particularly adaptable to be interposed between two stacked electronic devices.

### BACKGROUND OF THE ART

The electronics industry is entering into a heat constrained period of growth. The heat flux of electronic components is increasing and air cooling will no longer remove enough heat to maintain the desired operating temperatures of the microprocessors and other electronic components.

The maximum heat flux which is generally considered to be manageable by conventional air cooling is about 50 W/cm². As microprocessors and other electronic devices are developed which create a heat flux in excess of about 50 W/cm² the electronics industry is moving to liquid cooled heat sinks. One approach to such liquid cooled heat sinks is what is referred to as a microchannel heat sink. A microchannel heat sink has extremely small grooves formed in the material from which the heat sink is constructed so as to provide very thin fins separated by very thin microchannels. This provides a much larger surface area for the dissipation of heat. Combined with a forced liquid circulation system microchannel heat sinks provide one of the most promising solutions to the electronics industry's appetite for increased cooling capacity.

To date, microchannel heat sinks have been constructed from materials such as silicon, diamond, aluminum and copper, copper-tungsten composites, and ceramics such as beryllium oxide.

U.S. Pat. No. 5,099,311 to Bonde et al., the details of which are incorporated herein by reference, discloses a typical construction for a silicon microchannel heat sink including systems for delivery of coolant to the microchannels.

U.S. Pat. No. 5,099,910 to Walpole et al., the details of which are incorporated herein by reference, discloses a microchannel heat sink having U-shaped microchannels so that the direction of fluid flow alternates in adjacent microchannels so as to provide a more uniform temperature and thermal resistance on the surface of the heat sink. The Walpole et al. heat sinks are manufactured from silicon, a copper-tungsten composite such as Thermcon® or a ceramic such as beryllium oxide.

U.S. Pat. Nos. 6,457,515 and 6,675,875 to Vafai et al., the details of which are incorporated herein by reference, disclose multi-layer microchannel heat sinks having fluid flow in opposite directions in adjacent layers, so as to eliminate the temperature gradient in the direction of fluid flow across the heat sink.

U.S. Pat. No. 5,874,775 to Shiomi et al., the details of which are incorporated herein by reference, discloses a diamond heat sink.

U.S. Patent Publication No. 2003/0062149 to Goodson et al., the details of which are incorporated herein by reference, describes an electroosmotic microchannel cooling system.

There is a continuing need for improved materials for use in microchannel heat sinks to avoid some of the problems encountered with previously used materials. The present invention provides microchannel heat sink apparatus and methods of manufacturing the same from graphite materials. Although some graphite materials have been previously been used for the manufacture of conventional heat sinks having larger channels, it has not previously been proposed for use in microchannel heat sinks.

One example of a conventionally sized heat sink made from graphite material is shown in U.S. Pat. No. 6,771,502 to Getz, Jr. et al., and assigned to the assignee of the present invention.

In U.S. Pat. No. 6,245,400 to Tzeng, Getz, Jr. and Weber, an adhesive-coated sheet of compressed particles of exfoliated graphite is taught, and noted as especially useful as a thermal interface article. In addition, U.S. Pat. No. 6,482,520 to Tzeng discloses the use of sheets of compressed particles of exfoliated graphite as heat spreaders (referred to in the patent as thermal interfaces) for a heat source such as an electronic component. Indeed, such materials are commercially available from Advanced Energy Technology Inc. of Lakewood, Ohio as its eGraf® SpreaderShield class of materials.

Graphites are made up of layer planes of hexagonal arrays or networks of carbon atoms. These layer planes of hexagonally arranged carbon atoms are substantially flat and are oriented or ordered so as to be substantially parallel and equidistant to one another. The substantially flat, parallel equidistant sheets or layers of carbon atoms, usually referred to as graphene layers or basal planes, are linked or bonded together and groups thereof are arranged in crystallites. Highly ordered graphites consist of crystallites of considerable size, the crystallites being highly aligned or oriented with respect to each other and having well ordered carbon layers. In other words, highly ordered graphites have a high degree of preferred crystallite orientation. It should be noted that graphites possess anisotropic structures and thus exhibit or possess many properties that are highly directional such as thermal and electrical conductivity.

Briefly, graphites may be characterized as laminated structures of carbon, that is, structures consisting of superposed layers or laminae of carbon atoms joined together by weak van der Waals forces. In considering the graphite structure, two axes or directions are usually noted, to wit, the “c” axis or direction and the “a” axes or directions. For simplicity, the “c” axis or direction may be considered as the direction perpendicular to the carbon layers. The “a” axes or directions may be considered as the directions parallel to the carbon layers or the directions perpendicular to the “c” direction. The graphites suitable for manufacturing flexible graphite sheets possess a very high degree of orientation.

As noted above, the bonding forces holding the parallel layers of carbon atoms together are only weak van der Waals forces. Natural graphites can be treated so that the spacing between the superposed carbon layers or laminae can be appreciably opened up so as to provide a marked expansion in the direction perpendicular to the layers, that is, in the “c” direction, and thus form an expanded or intumesced graphite structure in which the laminar character of the carbon layers is substantially retained.

Graphite flake which has been greatly expanded and more particularly expanded so as to have a final thickness or “c” direction dimension which is as much as about 80 or more times the original “c” direction dimension can be formed without the use of a binder into cohesive or integrated sheets of expanded graphite, e.g. webs, papers, strips, tapes, foils, mats or the like (typically referred to as “flexible graphite”). The formation of graphite particles which have been expanded to have a final thickness or “c” dimension which is as much as about 80 times or more the original “c” direction dimension into integrated flexible sheets by compression, without the use of any binding material, is believed to be possible due to the mechanical interlocking, or cohesion, which is achieved between the voluminously expanded graphite particles.

In addition to flexibility, the sheet material, as noted above, has also been found to possess a high degree of anisotropy with respect to thermal conductivity due to orientation of the expanded graphite particles and graphite layers substantially parallel to the opposed faces of the sheet resulting from high compression, making it especially useful in heat spreading applications. Sheet material thus produced has excellent flexibility, good strength and a high degree of orientation.

Briefly, the process of producing flexible, binderless anisotropic graphite sheet material, e.g. web, paper, strip, tape, foil, mat, or the like, comprises compressing or compacting under a predetermined load and in the absence of a binder, expanded graphite particles which have a “c” direction dimension which is as much as about 80 or more times that of the original particles so as to form a substantially flat, flexible, integrated graphite sheet. The expanded graphite particles that generally are worm-like or vermiform in appearance, once compressed, will maintain the compression set and alignment with the opposed major surfaces of the sheet. The density and thickness of the sheet material can be varied by controlling the degree of compression. The density of the sheet material can be within the range of from about 0.04 g/cc to about 2.0 g/cc.

The flexible graphite sheet material exhibits an appreciable degree of anisotropy due to the alignment of graphite particles parallel to the major opposed, parallel surfaces of the sheet, with the degree of anisotropy increasing upon compression of the sheet material to increase orientation. In compressed anisotropic sheet material, the thickness, i.e. the direction perpendicular to the opposed, parallel sheet surfaces comprises the “c” direction and the directions ranging along the length and width, i.e. along or parallel to the opposed, major surfaces comprises the “a” directions and the thermal and electrical properties of the sheet are very different, by orders of magnitude, for the “c” and “a” directions.

Thus, what is desired is an economically manufactured microchannel heat sink made from graphite materials.

### SUMMARY OF THE INVENTION

Accordingly it is an object of the present invention to provide a microchannel heat sink manufactured from graphite materials.

Another object of the invention is to provide a microchannel heat sink which is relatively lightweight.

And another object of the present invention is to provide a microchannel heat sink manufactured from graphite materials which are inert to water and other conventional cooling liquids.

Still another object of the present invention is the provision of a microchannel heat sink made from graphite materials which has good thermal conductivity.

Still another object of the present invention is the provision of a microchannel heat sink manufactured from graphite materials which have a coefficient of thermal expansion comparable to that of typical semiconductor and ceramic materials used in electronics packaging.

And another object of the present invention is the provision of microchannel heat sinks manufactured from graphite materials in which the microchannels can be formed using high volume manufacturing methods such as roller embossing, thus allowing cost effective manufacture of materials.

Still another object of the present invention is the provision of microchannel heat sinks manufactured from graphite materials which are suitable to be interposed between two stacked electronic devices.

These objects and others which will be apparent to the skilled artisan upon reading the following description, can be achieved by providing an apparatus for cooling an electronic device, comprising a heat sink member having at least a first thermal contact surface for making thermal contact with the electronic device, said member being constructed of at least a first sheet of compressed particles of exfoliated graphite, said sheet having two major surfaces, and at least one of said major surfaces having a first plurality of microchannels formed therein for carrying coolant fluid, said microchannels each having a length parallel to said one of said major surfaces and having a cross-section normal to said length, said cross-section having at least one dimension below about 1,000 microns.

In another embodiment, the apparatus includes a second sheet of compressed particles of exfoliated graphite, the first and second sheets being joined together to define the cross-section of the microchannels. First and second thermal contact surfaces are defined on opposite surfaces of the heat sink member, so that the heat sink member may be interposed between two stacked electronic devices.

In another embodiment of the apparatus for cooling an electronic device, the heat sink member may be constructed from first, second and third sheets of compressed particles of exfoliated graphite. Two layers of microchannels are defined at the interfaces between the three sheets so that first and second pluralities of microchannels may carry coolant fluid in opposite directions.

In another embodiment of the invention a liquid cooled electronic apparatus is provided having first and second stacked electronic devices operable under conditions of high heat flux density. A heat sink member is interposed between, and in thermal contact with each of, said first and second stacked electronic devices. The heat sink member is constructed of at least two sheets of flexible graphite material having major surfaces thereof joined together, at least one of said major surfaces of one of said sheets having a plurality of microchannels formed therein for carrying coolant liquid between the two stacked electronic devices.

In another embodiment of the invention a method of manufacturing a microchannel heat sink from graphite materials is provided. First and second sheets of flexible graphite material are provided, each sheet having two major surfaces. A plurality of microchannels are formed in at least one of said major surfaces of said first sheet. The second sheet is superimposed upon the first sheet and adjacent major surfaces of said first and second sheets are joined together to close a cross-section of the microchannels. A thermal contact surface is provided on an exposed major surface of at least one of the first and second sheets for mounting an electronic device. Alternatively thermal contact surfaces can be provided on both exposed major surfaces so that the microchannel heat sink may be interposed between two stacked electronic devices. The microchannels are preferably formed by roller embossing the flexible graphite sheet.

It is to be understood that both the foregoing general description and the following detailed description provide embodiments of the invention and are intended to provide an overview or framework of understanding and nature and character of the invention as it is claimed. The accompanying drawings are included to provide a further understanding of the invention and are incorporated in and constitute a part of the specification. The drawings illustrate various embodiments of the invention and together with the description serve to describe the principles and operations of the invention.

### BRIEF DESCRIPTION OF THE DRAWINGS

FIG. 1 is a perspective view of a first embodiment of a microchannel heat sink.

FIG. 2 is a perspective view of a second embodiment of a microchannel heat sink.

FIG. 3 is an end view of a microchannel heat sink like that of FIG. 1 having a first electronic device mounted thereon with a thermal interface between the electronic device and the microchannel heat sink.

FIG. 4 is an end view of a microchannel heat sink like that of FIG. 1 having first and second stacked electronic devices mounted on opposite sides thereof

FIG. 5 is an end view of a microchannel heat sink like that of FIG. 1.

FIG. 6 is an end view of a microchannel heat sink like that of FIG. 2.

FIG. 7 is an end view of an alternative microchannel heat sink made up of three sheets of flexible graphite material, with the two outer sheets having microchannels formed therein and the middle sheet forming a cap on the microchannels of both of the outer sheets. This construction provides two layers of microchannels.

FIG. 8 is an end view of a microchannel heat sink constructed from three sheets of flexible graphite material, with the middle sheet having microchannels formed on each major surface thereof and with the two outer sheets forming caps on the microchannels of the middle sheet. This construction provides two layers of microchannels.

FIG. 9 is an end view of a microchannel heat sink constructed from four sheets of flexible graphite material, with each of the two innermost sheets having microchannels formed on their outermost major surfaces and with the two outer sheets forming caps on the microchannels of the two inner sheets. This construction provides two layers of microchannels.

FIG. 10 is an end view of another embodiment of the invention formed from four sheets of flexible graphite material, wherein each sheet has microchannels formed therein and the microchannels of each of two pairs of adjacent sheets are complementary to and superimposed on each other to form two layers of microchannels.

FIG. 11a,b are photomicrographs of a cross-section of a sheet of flexible graphite material which has had microchannels formed therein by embossing.

FIG. 12 shows a system for the continuous production of resin-impregnated flexible graphite sheets.

### DETAILED DESCRIPTION OF THE PREFERRED EMBODIMENT

Graphite is a crystalline form of carbon comprising atoms covalently bonded in flat layered planes with weaker bonds between the planes. In obtaining source materials such as the above flexible sheets of graphite, particles of graphite, such as natural graphite flake, are typically treated with an intercalant of, e.g. a solution of sulfuric and nitric acid, where the crystal structure of the graphite reacts to form a compound of graphite and the intercalant. The treated particles of graphite are hereafter referred to as “particles of intercalated graphite.” Upon exposure to high temperature, the intercalant within the graphite decomposes and volatilizes, causing the particles of intercalated graphite to expand in dimension as much as about 90 or more times its original volume in an accordion-like fashion in the “c” direction, i.e. in the direction perpendicular to the crystalline planes of the graphite. The expanded (otherwise referred to as exfoliated) graphite particles are vermiform in appearance, and are therefore commonly referred to as worms. The worms may be compressed together into flexible sheets that, unlike the original graphite flakes, can be formed and cut into various shapes and provided with small transverse openings by deforming mechanical impact.

Graphite starting materials for the flexible sheets suitable for use in the present invention include highly graphitic carbonaceous materials capable of intercalating organic and inorganic acids as well as halogens and then expanding when exposed to heat. These highly graphitic carbonaceous materials most preferably have a degree of graphitization of about 1.0. As used in this disclosure, the term “degree of graphitization” refers to the value g according to the formula:

$$g = \frac{3.45 - d ( 002 )}{0.095}$$

where d(002) is the spacing between the graphitic layers of the carbons in the crystal structure measured in Angstrom units. The spacing d between graphite layers is measured by standard X-ray diffraction techniques. The positions of diffraction peaks corresponding to the (002), (004) and (006) Miller Indices are measured, and standard least-squares techniques are employed to derive spacing which minimizes the total error for all of these peaks. Examples of highly graphitic carbonaceous materials include natural graphites from various sources, as well as other carbonaceous materials such as graphite prepared by chemical vapor deposition, high temperature pyrolysis of polymers, or crystallization from molten metal solutions, and the like. Natural graphite is most preferred.

The graphite starting materials for the flexible sheets used in the present invention may contain non-graphite components so long as the crystal structure of the starting materials maintains the required degree of graphitization and they are capable of exfoliation. Generally, any carbon-containing material, the crystal structure of which possesses the required degree of graphitization and which can be exfoliated, is suitable for use with the present invention. Such graphite preferably has an ash content of less than twenty weight percent. More preferably, the graphite employed for the present invention will have a purity of at least about 94%. In the most preferred embodiment, the graphite employed will have a purity of at least about 98%.

A common method for manufacturing graphite sheet is described by Shane et al. in U.S. Pat. No. 3,404,061, the disclosure of which is incorporated herein by reference. In the typical practice of the Shane et al. method, natural graphite flakes are intercalated by dispersing the flakes in a solution containing e.g., a mixture of nitric and sulfuric acid, advantageously at a level of about 20 to about 300 parts by weight of intercalant solution per 100 parts by weight of graphite flakes (pph). The intercalation solution contains oxidizing and other intercalating agents known in the art. Examples include those containing oxidizing agents and oxidizing mixtures, such as solutions containing nitric acid, potassium chlorate, chromic acid, potassium permanganate, potassium chromate, potassium dichromate, perchloric acid, and the like, or mixtures, such as for example, concentrated nitric acid and chlorate, chromic acid and phosphoric acid, sulfuric acid and nitric acid, or mixtures of a strong organic acid, e.g. trifluoroacetic acid, and a strong oxidizing agent soluble in the organic acid. Alternatively, an electric potential can be used to bring about oxidation of the graphite. Chemical species that can be introduced into the graphite crystal using electrolytic oxidation include sulfuric acid as well as other acids.

In a preferred embodiment, the intercalating agent is a solution of a mixture of sulfuric acid, or sulfuric acid and phosphoric acid, and an oxidizing agent, i.e. nitric acid, perchloric acid, chromic acid, potassium permanganate, hydrogen peroxide, iodic or periodic acids, or the like. Although less preferred, the intercalation solution may contain metal halides such as ferric chloride, and ferric chloride mixed with sulfuric acid, or a halide, such as bromine as a solution of bromine and sulfuric acid or bromine in an organic solvent.

The quantity of intercalation solution may range from about 20 to about 350 pph and more typically about 40 to about 160 pph. After the flakes are intercalated, any excess solution is drained from the flakes and the flakes are water-washed.

Alternatively, the quantity of the intercalation solution may be limited to between about 10 and about 40 pph, which permits the washing step to be eliminated as taught and described in U.S. Pat. No. 4,895,713, the disclosure of which is also herein incorporated by reference.

The particles of graphite flake treated with intercalation solution can optionally be contacted, e.g. by blending, with a reducing organic agent selected from alcohols, sugars, aldehydes and esters which are reactive with the surface film of oxidizing intercalating solution at temperatures in the range of 25° C. and 125° C. Suitable specific organic agents include hexadecanol, octadecanol, 1-octanol, 2-octanol, decylalcohol, 1, 10 decanediol, decylaldehyde, 1-propanol, 1,3 propanediol, ethyleneglycol, polypropylene glycol, dextrose, fructose, lactose, sucrose, potato starch, ethylene glycol monostearate, diethylene glycol dibenzoate, propylene glycol monostearate, glycerol monostearate, dimethyl oxylate, diethyl oxylate, methyl formate, ethyl formate, ascorbic acid and lignin-derived compounds, such as sodium lignosulfate. The amount of organic reducing agent is suitably from about 0.5 to 4% by weight of the particles of graphite flake.

The use of an expansion aid applied prior to, during or immediately after intercalation can also provide improvements. Among these improvements can be reduced exfoliation temperature and increased expanded volume (also referred to as “worm volume”). An expansion aid in this context will advantageously be an organic material sufficiently soluble in the intercalation solution to achieve an improvement in expansion. More narrowly, organic materials of this type that contain carbon, hydrogen and oxygen, preferably exclusively, may be employed. Carboxylic acids have been found especially effective. A suitable carboxylic acid useful as the expansion aid can be selected from aromatic, aliphatic or cycloaliphatic, straight chain or branched chain, saturated and unsaturated monocarboxylic acids, dicarboxylic acids and polycarboxylic acids which have at least 1 carbon atom, and preferably up to about 15 carbon atoms, which is soluble in the intercalation solution in amounts effective to provide a measurable improvement of one or more aspects of exfoliation. Suitable organic solvents can be employed to improve solubility of an organic expansion aid in the intercalation solution.

Representative examples of saturated aliphatic carboxylic acids are acids such as those of the formula H(CH₂)ₙCOOH wherein n is a number of from 0 to about 5, including formic, acetic, propionic, butyric, pentanoic, hexanoic, and the like. In place of the carboxylic acids, the anhydrides or reactive carboxylic acid derivatives such as alkyl esters can also be employed. Representative of alkyl esters are methyl formate and ethyl formate. Sulfuric acid, nitric acid and other known aqueous intercalants have the ability to decompose formic acid, ultimately to water and carbon dioxide. Because of this, formic acid and other sensitive expansion aids are advantageously contacted with the graphite flake prior to immersion of the flake in aqueous intercalant. Representative of dicarboxylic acids are aliphatic dicarboxylic acids having 2-12 carbon atoms, in particular oxalic acid, fumaric acid, malonic acid, maleic acid, succinic acid, glutaric acid, adipic acid, 1,5-pentanedicarboxylic acid, 1,6-hexanedicarboxylic acid, 1,10-decanedicarboxylic acid, cyclohexane-1,4-dicarboxylic acid and aromatic dicarboxylic acids such as phthalic acid or terephthalic acid. Representative of alkyl esters are dimethyl oxylate and diethyl oxylate. Representative of cycloaliphatic acids is cyclohexane carboxylic acid and of aromatic carboxylic acids are benzoic acid, naphthoic acid, anthranilic acid, p-aminobenzoic acid, salicylic acid, o-, m- and p-tolyl acids, methoxy and ethoxybenzoic acids, acetoacetamidobenzoic acids and, acetamidobenzoic acids, phenylacetic acid and naphthoic acids. Representative of hydroxy aromatic acids are hydroxybenzoic acid, 3-hydroxy-1-naphthoic acid, 3-hydroxy-2-naphthoic acid, 4-hydroxy-2-naphthoic acid, 5-hydroxy-1-naphthoic acid, 5-hydroxy-2-naphthoic acid, 6-hydroxy-2-naphthoic acid and 7-hydroxy-2-naphthoic acid. Prominent among the polycarboxylic acids is citric acid.

The intercalation solution will be aqueous and will preferably contain an amount of expansion aid of from about 1 to 10%, the amount being effective to enhance exfoliation. In the embodiment wherein the expansion aid is contacted with the graphite flake prior to or after immersing in the aqueous intercalation solution, the expansion aid can be admixed with the graphite by suitable means, such as a V-blender, typically in an amount of from about 0.2% to about 10% by weight of the graphite flake.

After intercalating the graphite flake, and following the blending of the intercalated graphite flake with the organic reducing agent, the blend can be exposed to temperatures in the range of 25° to 125° C. to promote reaction of the reducing agent and intercalated graphite flake. The heating period is up to about 20 hours, with shorter heating periods, e.g., at least about 10 minutes, for higher temperatures in the above-noted range. Times of one-half hour or less, e.g., on the order of 10 to 25 minutes, can be employed at the higher temperatures.

The above described methods for intercalating and exfoliating graphite flake may beneficially be augmented by a pretreatment of the graphite flake at graphitization temperatures, i.e. temperatures in the range of about 3000° C. and above and by the inclusion in the intercalant of a lubricious additive.

The pretreatment, or annealing, of the graphite flake results in significantly increased expansion (i.e., increase in expansion volume of up to 300% or greater) when the flake is subsequently subjected to intercalation and exfoliation. Indeed, desirably, the increase in expansion is at least about 50%, as compared to similar processing without the annealing step. The temperatures employed for the annealing step should not be significantly below 3000° C., because temperatures even 100° C. lower result in substantially reduced expansion.

The annealing of the present invention is performed for a period of time sufficient to result in a flake having an enhanced degree of expansion upon intercalation and subsequent exfoliation. Typically the time required will be 1 hour or more, preferably 1 to 3 hours and will most advantageously proceed in an inert environment. For maximum beneficial results, the annealed graphite flake will also be subjected to other processes known in the art to enhance the degree expansion—namely intercalation in the presence of an organic reducing agent, an intercalation aid such as an organic acid, and a surfactant wash following intercalation. Moreover, for maximum beneficial results, the intercalation step may be repeated.

The annealing step of the instant invention may be performed in an induction furnace or other such apparatus as is known and appreciated in the art of graphitization; for the temperatures here employed, which are in the range of 3000° C., are at the high end of the range encountered in graphitization processes.

Because it has been observed that the worms produced using graphite subjected to pre-intercalation annealing can sometimes “clump” together, which can negatively impact area weight uniformity, an additive that assists in the formation of “free flowing” worms is highly desirable. The addition of a lubricious additive to the intercalation solution facilitates the more uniform distribution of the worms across the bed of a compression apparatus (such as the bed of a calender station conventionally used for compressing (or “calendering”) graphite worms into flexible graphite sheet. The resulting sheet therefore has higher area weight uniformity and greater tensile strength, even when the starting graphite particles are smaller than conventionally used. The lubricious additive is preferably a long chain hydrocarbon. Other organic compounds having long chain hydrocarbon groups, even if other functional groups are present, can also be employed.

More preferably, the lubricious additive is an oil, with a mineral oil being most preferred, especially considering the fact that mineral oils are less prone to rancidity and odors, which can be an important consideration for long term storage. It will be noted that certain of the expansion aids detailed above also meet the definition of a lubricious additive. When these materials are used as the expansion aid, it may not be necessary to include a separate lubricious additive in the intercalant.

The lubricious additive is present in the intercalant in an amount of at least about 1.4 pph, more preferably at least about 1.8 pph. Although the upper limit of the inclusion of lubricous additive is not as critical as the lower limit, there does not appear to be any significant additional advantage to including the lubricious additive at a level of greater than about 4 pph.

The thus treated particles of graphite are sometimes referred to as “particles of intercalated graphite.” Upon exposure to high temperature, e.g. temperatures of at least about 160° C. and especially about 700° C. to 1000° C. and higher, the particles of intercalated graphite expand as much as about 90 to 1000 or more times their original volume in an accordion-like fashion in the c-direction, i.e. in the direction perpendicular to the crystalline planes of the constituent graphite particles. The expanded, i.e. exfoliated, graphite particles are vermiform in appearance, and are therefore commonly referred to as worms. The worms may be compression molded together into flexible sheets having small transverse openings that, unlike the original graphite flakes, can be formed and cut into various shapes, as hereinafter described.

Alternatively, the flexible graphite sheets of the present invention may utilize particles of reground flexible graphite sheets rather than freshly expanded worms. The sheets may be newly formed sheet material, recycled sheet material, scrap sheet material, or any other suitable source.

Also the processes of the present invention may use a blend of virgin materials and recycled materials, or all recycled materials.

The source material for recycled materials may be sheets or trimmed portions of sheets that have been compression molded as described above, or sheets that have been compressed with, for example, pre-calendering rolls. Furthermore, the source material may be sheets or trimmed portions of sheets that have been impregnated with resin, but not yet cured, or sheets or trimmed portions of sheets that have been impregnated with resin and cured. The source material may also be recycled flexible graphite PEM fuel cell components such as flow field plates or electrodes. Each of the various sources of graphite may be used as is or blended with natural graphite flakes.

Once the source material of flexible graphite sheets is available, it can then be comminuted by known processes or devices, such as a jet mill, air mill, blender, etc. to produce particles. Preferably, a majority of the particles have a diameter such that they will pass through 20 U.S. mesh; more preferably a major portion (greater than about 20%, most preferably greater than about 50%) will not pass through 80 U.S. mesh. Most preferably the particles have a particle size of no greater than about 20 mesh.

The size of the comminuted particles may be chosen so as to balance machinability and formability of the graphite article with the thermal characteristics desired. Thus, smaller particles will result in a graphite article which is easier to machine and/or form, whereas larger particles will result in a graphite article having higher anisotropy, and, therefore, greater in-plane electrical and thermal conductivity.

Once the source material is comminuted, and any resin is removed if desired, it is then re-expanded. The re-expansion may occur by using the intercalation and exfoliation process described above and those described in U.S. Pat. No. 3,404,061 to Shane et al. and U.S. Pat. No. 4,895,713 to Greinke et al.

Typically, after intercalation the particles are exfoliated by heating the intercalated particles in a furnace. During this exfoliation step, intercalated natural graphite flakes may be added to the recycled intercalated particles. Preferably, during the re-expansion step the particles are expanded to have a specific volume in the range of at least about 100 cc/g and up to about 350 cc/g or greater. Finally, after the re-expansion step, the re-expanded particles may be compressed into flexible sheets, as hereinbefore described.

Flexible graphite sheet and foil are coherent, with good handling strength, and are suitably compressed by, e.g. compression molding, to a thickness of about 0.025 mm to 3.75 mm and a typical density of about 0.1 to 1.5 grams per cubic centimeter (g/cc). Although not always preferred, the flexible graphite sheet can also, at times, be advantageously treated with resin and the absorbed resin, after curing, enhances the moisture resistance and handling strength, i.e. stiffness, of the flexible graphite sheet as well as “fixing” the morphology of the sheet. When used, a suitable resin content is preferably at least about 5% by weight, more preferably about 10 to 35% by weight, and suitably up to about 60% by weight. Resins found especially useful in the practice of the present invention include acrylic-, epoxy- and phenolic-based resin systems, or mixtures thereof Suitable epoxy resin systems include those based on diglycidyl ether or bisphenol A (DGEBA) and other multifunctional resin systems; phenolic resins that can be employed include resole and novolak phenolics. Optionally, the flexible graphite may be impregnated with fibers and/or salts in addition to the resin or in place of the resin. Additionally, reactive or non-reactive additives may be employed with the resin system to modify properties (such as tack, material flow, hydrophobicity, etc.). In order to maximize the thermal conductivity of the resin-impregnated materials, the resin can be cured at elevated temperatures and pressure. More particularly, cure at temperatures of at least about 90° C. and pressures of at least about 7 megapascals (MPa) will produce graphite materials having superior thermal conductivities (indeed, in-plane thermal conductivities in excess of those observed with copper can be achieved).

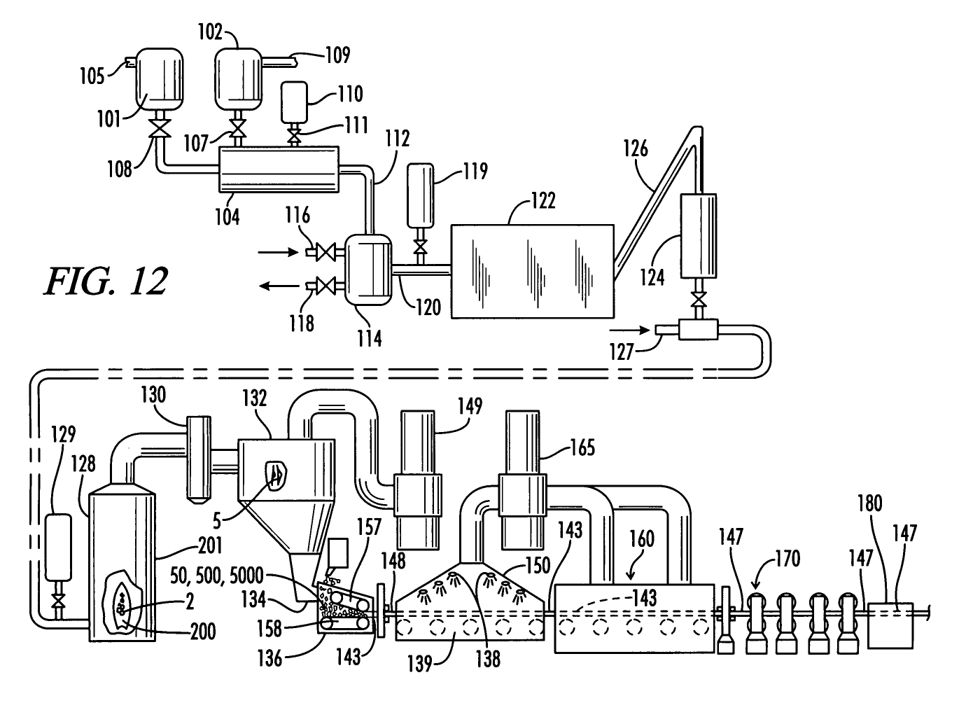

With reference to FIG. 12, a system is disclosed for the continuous production of resin-impregnated flexible graphite sheet, where graphite flakes and a liquid intercalating agent are charged into reactor 104. More particularly, a vessel 101 is provided for containing a liquid intercalating agent. Vessel 101, suitably made of stainless steel, can be continually replenished with liquid intercalant by way of conduit 106. Vessel 102 contains graphite flakes that, together with intercalating agents from vessel 101, are introduced into reactor 104. The respective rates of input into reactor 104 of intercalating agent and graphite flake are controlled, such as by valves 108, 107. Graphite flake in vessel 102 can be continually replenished by way of conduit 109. Additives, such as intercalation enhancers, e.g., trace acids, and organic chemicals may be added by way of dispenser 110 that is metered at its output by valve 111.

The resulting intercalated graphite particles are soggy and acid coated and are conducted (such as via conduit 112) to a wash tank 114 where the particles are washed, advantageously with water which enters and exits wash tank 114 at 116, 118. The washed intercalated graphite flakes are then passed to drying chamber 122 such as through conduit 120. Additives such as buffers, antioxidants, pollution reducing chemicals can be added from vessel 119 to the flow of intercalated graphite flake for the purpose of modifying the surface chemistry of the exfoliate during expansion and use and modifying the gaseous emissions which cause the expansion.

The intercalated graphite flake is dried in dryer 122, preferably at temperatures of about 75° C. to about 150° C., generally avoiding any intumescence or expansion of the intercalated graphite flakes. After drying, the intercalated graphite flakes are fed as a stream into flame 200, by, for instance, being continually fed to collecting vessel 124 by way of conduit 126 and then fed as a stream into flame 200 in expansion vessel 128 as indicated at 2. Additives such as ceramic fiber particles formed of macerated quartz glass fibers, carbon and graphite fibers, zirconia, boron nitride, silicon carbide and magnesia fibers, naturally occurring mineral fibers such as calcium metasilicate fibers, calcium aluminum silicate fibers, aluminum oxide fibers and the like can be added from vessel 129 to the stream of intercalated graphite particles propelled by entrainment in a non-reactive gas introduced at 127.

The intercalated graphite particles 2, upon passage through flame 200 in expansion chamber 201, expand more than 80 times in the “c” direction and assume a “worm-like” expanded form 5; the additives introduced from 129 and blended with the stream of intercalated graphite particles are essentially unaffected by passage through the flame 200. The expanded graphite particles 5 may pass through a gravity separator 130, in which heavy ash natural mineral particles are separated from the expanded graphite particles, and then into a wide topped hopper 132. Separator 130 can be by-passed when not needed.

The expanded, i.e., exfoliated graphite particles 5 fall freely in hopper 132 together with any additives, and are randomly dispersed and passed into compression station 136, such as through trough 134. Compression station 136 comprises opposed, converging, moving porous belts 157, 158 spaced apart to receive the exfoliated, expanded graphite particles 5. Due to the decreasing space between opposed moving belts 157, 158, the exfoliated expanded graphite particles are compressed into a mat of flexible graphite, indicated at 148 having thickness of, e.g., from about 25.4 to 0.075 mm, especially from about 25.4 to 2.5 mm, and a density of from about 0.08 to 2.0 g/cm³. Gas scrubber 149 may be used to remove and clean gases emanating from the expansion chamber 201 and hopper 132.

The mat 148 is passed through vessel 150 and is impregnated with liquid resin from spray nozzles 138, the resin advantageously being “pulled through the mat” by means of vacuum chamber 139 and the resin is thereafter preferably dried in dryer 160 reducing the tack of the resin and the resin impregnated mat 143 is thereafter densified into roll pressed flexible graphite sheet 147 in calender mill 170. Gases and fumes from vessel 150 and dryer 160 are preferably collected and cleaned in scrubber 165.

After densification, the resin in flexible graphite sheet 147 is at least partially cured in curing oven 180. Alternatively, partial cure can be effected prior to densification, although post-densification cure is preferred.

In one embodiment of the invention, however, the flexible graphite sheet is not resin-impregnated, in which case vessel, 150, dryer 160 and curing oven 180 can be eliminated.

The resin-impregnated sheet, which has a starting density of about 0.1 to about 1.1 g/cc, is thereafter processed to change the void condition of the sheet. By void condition is meant the percentage of the sheet represented by voids, which are generally found in the form of entrapped air. Generally, this is accomplished by the application of pressure to the sheet (which also has the effect of densifying the sheet) so as to reduce the level of voids in the sheet, for instance in a calender mill or platen press. Advantageously, the flexible graphite sheet is densified to a density of at least about 1.3 g/cc (although the presence of resin in the system can be used to reduce the voids without requiring densification to so high a level).

The void condition can be used advantageously to control and adjust the morphology and functional characteristics of the final embossed article. For instance, thermal and electrical conductivity, permeation rate and leaching characteristics can be effected and potentially controlled by controlling the void condition (and, usually, the density) of the sheet prior to embossing. Thus, if a set of desired characteristics of the final embossed article is recognized prior to manipulation of the void condition, the void condition can be tailored to achieve those characteristics, to the extent possible.

Advantageously, especially when the final embossed article is intended for use as a component in an electrochemical fuel cell, the resin-impregnated flexible graphite sheet is manipulated so as to be relatively void-free, to optimize electrical and thermal conductivities. Generally, this is accomplished by achieving a density of at least about 1.4 g/cc, more preferably at least about 1.6 g/cc (depending on resin content), indicating a relatively void-free condition. The thermal conductivity of the sheet is preferably at least about 140 W/m° K., more preferably at least about 400 W/m° K.

The calendered flexible graphite sheet is then passed through an embossing apparatus as described herein below, and thereafter heated in an oven to cure the resin. Depending on the nature of the resin system employed, and especially the solvent type and level employed (which is advantageously tailored to the specific resin system, as would be familiar to the skilled artisan), a vaporization drying step may be included prior to the embossing step. In this drying step, the resin impregnated flexible graphite sheet is exposed to heat to vaporize and thereby remove some or all of the solvent, without effecting cure of the resin system. In this way, blistering during the curing step, which can be caused by vaporization of solvent trapped within the sheet by the densification of the sheet during surface shaping, is avoided. The degree and time of heating will vary with the nature and amount of solvent, and is preferably at a temperature of at least about 65° C. and more preferably from about 80° C. to about 95° C. for about 3 to about 20 minutes for this purpose.

One embodiment of an apparatus for continuously forming resin-impregnated and calendared flexible graphite sheet is shown in International Publication No. WO 00/64808 the disclosure of which is incorporated herein by reference.

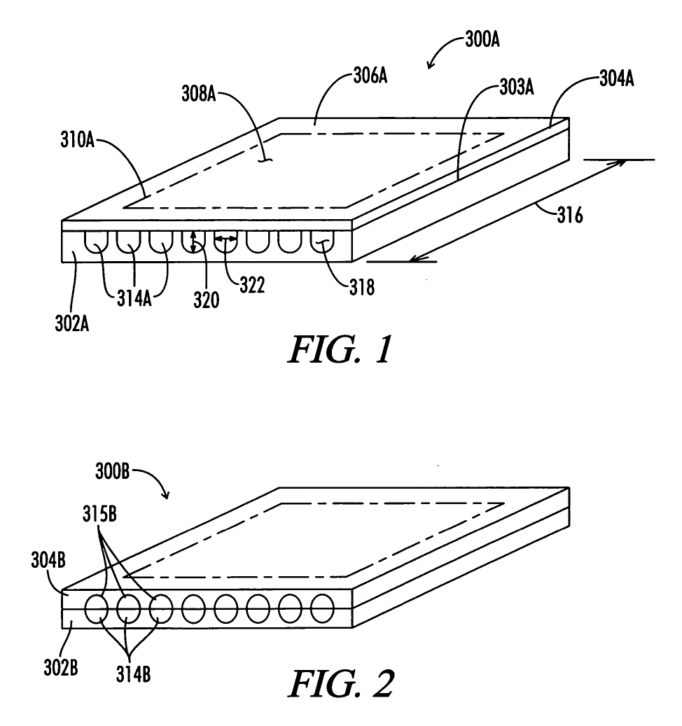

Referring now to FIG. 1, a first embodiment of a heat sink member 300A, which may also be referred to as an apparatus for cooling an electronic device, is shown. The heat sink member 300A is constructed of first and second sheets 302A and 304A of compressed particles of exfoliated graphite. The sheets 302A and 304A may also be described as flexible graphite sheets.

Each of the sheets 302A and 304A has two major surfaces which in FIG. 1 are the larger planar upper and lower surfaces. In FIG. 1 the upper major surface 306A of second sheet 304A is visible.

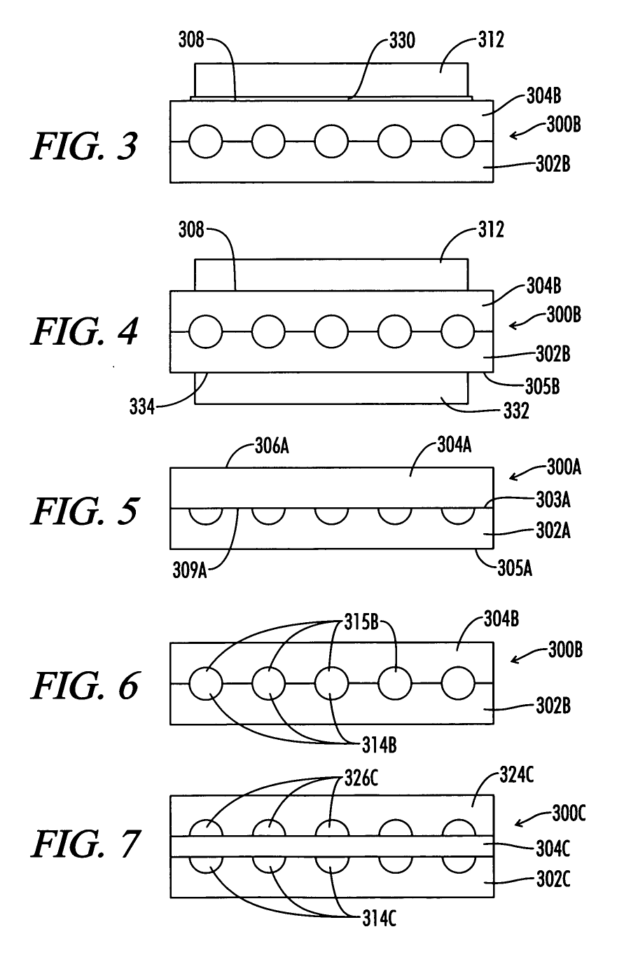

A thermal contact surface 308A is defined on major surface 306A and is designated by the generally rectangular phantom line 310A. The thermal contact surface 308A is provided for making thermal contact with an electronic device like device 312 shown in FIG. 3.

In the embodiment of FIG. 1, the upper major surface 303A of the first sheet 302A has a first plurality of microchannels 314A formed therein for carrying coolant fluid such as water. The microchannels 314A each have a length 316 parallel to the major surfaces and have a cross-section 318 normal to the length 316. The cross-section 318 has a depth 320 and a width 322 which are dimensions of the cross-section. The cross-section 318 has at least one such dimension below about 1,000 microns. For example, the width 322 may be below about 1,000 microns. In many cases, both the width and the depth will be less than 1,000 microns, thus providing a cross-sectional area of the microchannel less than 10⁶ square microns.

Preferably said one dimension such as the width 322 is at least about 100 microns. In some instances said one dimension such as the width 322 may even be less than 100 microns.

It will be appreciated that in all of the figures the microchannels are shown in somewhat schematic form and are not dimensionally to scale in comparison to the width, thickness and length of the sheets of flexible graphite material.

The second sheet 304A is joined to the first sheet 302A so that the first and second sheets together define the cross-section 318 of the microchannels 314A. In the embodiment of FIG. 1, the second sheet 304A is a flat sheet without microchannels and defines a cap on the microchannels of the first sheet 302A.

The first and second sheets 302A and 304A are joined together by superimposing their adjacent major surfaces and bonding the same together. This bonding may be provided by applying a resin to one or both of the major surfaces or in the case of flexible graphite sheet which is resin impregnated, the resin is already present in the sheets and the same are bonded together by holding the sheets in intimate contact while curing the sheets.

Referring now to the end view of FIG. 5, the first sheet 302A has upper and lower major surfaces 303A and 305A, respectively. The second sheet 304A has the upper major surface 306A and a lower major surface 309A.

Turning now to FIGS. 2 and 5 an alternative embodiment of the microchannel heat sink is designated by the numeral 300B. The heat sink member 300B is constructed from a first sheet 302B and a second sheet 304B. The difference between heat sink members 300B of FIG. 2 and 300A of FIG. 1 is that in the embodiment of FIG. 2 the second sheet 300B also has microchannels 315B formed therein. The microchannels 315B are defined in a pattern complementary to and superimposed upon the microchannels 314B of the first sheet 302B, so that each microchannel through the heat sink member 300B has a top half defined by one of the microchannels 315B and a bottom half defined by one of the microchannels 314B.

It will be appreciated that in the numbering of the elements of the embodiment of FIG. 2, and the subsequent embodiments of FIGS. 7-10, like numbers are being used for analogous components, with a different postscript A, B, C, etc. being utilized for each of the embodiments.

FIG. 7 shows an end view of another embodiment of a heat sink member designated by the numeral 300C. The heat sink member 300C is constructed of a first sheet 302C, a second flexible graphite sheet 304C and a third flexible graphite sheet 324C.

The first sheet 302C has the first plurality of microchannels 314C defined therein. The third sheet 324C has a second plurality of microchannels 326C. The middle sheet 304C is a flat sheet sandwiched between the first and third sheets 302C and 324C and serving as a cap on the microchannels of each of the first and third sheets so that microchannels 314C and the second plurality of microchannels 326C define two parallel but isolated layers of microchannels. Thus in the embodiment of FIG. 7, the possibility is provided for having fluid flow in one direction through the first layer of microchannels 314C and in the opposite direction through the second layer of microchannels 326C. As will be appreciated by those skilled in the art, by providing opposite flows in alternating layers of microchannels, a more uniform heat distribution is provided through the heat sink member. This is because the fluid flowing through the microchannels increases in temperature as it travels through the microchannel, thus providing a heat gradient along the length of the microchannel. By having fluid flow in opposite directions through two parallel layers of microchannels, the heat gradient for each layer increases in an opposite direction from that of the adjacent layer, thus providing a relatively uniform heating across the entire heat sink member.

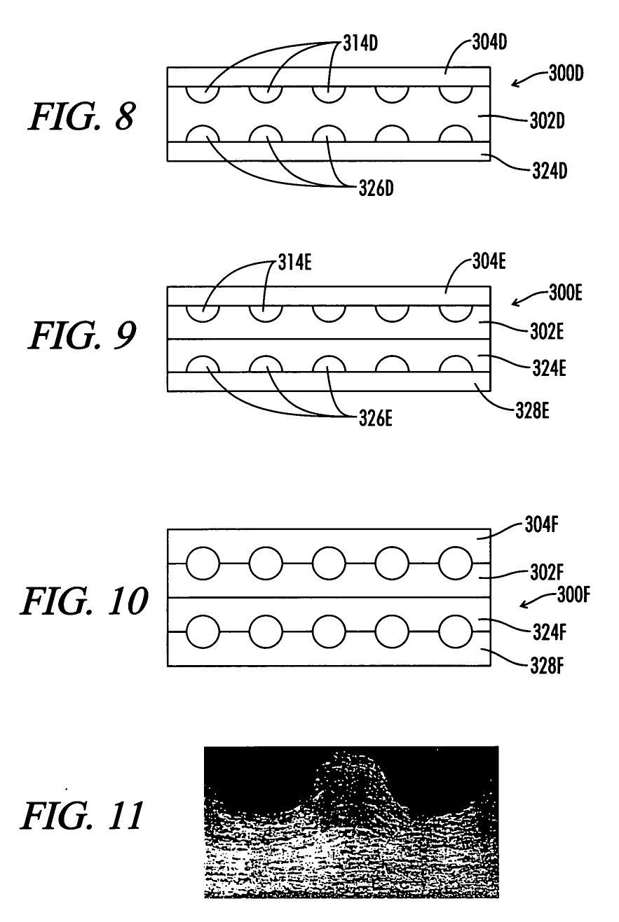

FIG. 8. shows still another alternative embodiment designated as 300D which is constructed from first sheet 302D, second sheet 304D and third sheet 324D.

The first sheet 304D in this case has a first plurality of microchannels 314D formed in the upper major surface thereof and a second plurality of microchannels 326D formed in the lower major surface thereof. Each of the second and third sheets 304D and 324D are flat sheets which serve as caps on the microchannels 314D and 326D, respectively. Thus the embodiment of FIG. 8 again provides two parallel layers of microchannels which can permit fluid flow in opposite directions through adjacent layers.

Turning now to FIG. 9, another embodiment of the heat sink member is designated by the numeral 300E. The heat sink member 300E includes a first sheet 302E and a second sheet 304E which are constructed similar to the first and second sheets of the heat sink member 300A of FIGS. 1 and 5. Heat sink member 300E further includes third and fourth sheets 324E and 328E. The third sheet 324E has a second plurality of microchannels 326E defined therein. The fourth sheet 328E is a flat sheet which serves to cap the microchannels 326E.

FIG. 10 shows still another embodiment of a heat sink member designated by the numeral 300F. The heat sink member 300F includes four flexible graphite sheets 302F, 304F, 324F and 328F. In this instance each of the sheets has a plurality of microchannels defined therein. The microchannels of the first and second sheets 302F and 304F are complementary to and superimposed upon each other like the microchannels of sheets 302B and 304B of FIGS. 2 and 6. The second pair of sheets 324F and 328F also have complementary microchannels defined therein, so that the four sheets together provide two layers of spaced microchannels and thus provide the ability for the heat sink member 300F to carry fluid in opposite directions in the two layers.

Turning now to FIG. 3, an end view is there shown of the heat sink member 300B of FIGS. 2 and 6. The electronic device 312, which may be a microprocessor chip or other conventional electronic device, is shown mounted upon the thermal contact surface 308.

A thermal interface 330 formed from a sheet of anisotropic flexible graphite material is attached to the second sheet 304B of the heat sink member 300B and defines the first thermal contact surface 308 of the heat sink member 300B. It will be appreciated that the use of the thermal interface 330 is optional. A preferred construction for the thermal interface 330 is shown in U.S. Pat. No. 6,746,768, assigned to the assignee of the present invention, which is incorporated herein by reference.

As shown in FIG. 4, the heat sink member 300B may be interposed between two stacked electronic devices 312 and 332. The second electronic device 332 is mounted on a second thermal contact surface 334 defined on the bottom surface 305B of sheet 302B. Thermal interfaces such as 330 may be provided between the heat sink member 300B and either or both of the electronic devices 312 and 332.

It will be appreciated that an arrangement like that of FIG. 4 provides for a very high density of electronic devices while still providing adequate cooling therebetween through the use of the microchannel heat sink member 300B. Any of the various alternative constructions of the heat sink member 300 shown in FIGS. 5-10 may be mounted with either a single electronic device 312 or interposed between two electronic devices 312 and 332 as shown in FIGS. 3 and 4, respectively.

The microchannel heat sinks are particularly intended for use with electronic devices 312 and 332 which are operable under conditions of high heat flux density which is generally considered to be greater than 50 W/cm².

Each of the sheets such as sheet 302A which has microchannels defined therein preferably has a thickness in the range of from about 0.4 mm to about 3.75 mm. Preferably the sheet has a thickness of no greater than about 2.0 mm. Even more preferably the sheet has a thickness of no greater than about 1.0 mm.

The microchannel heat sinks manufactured from graphite materials described herein have a number of advantages over microchannel heat sinks made from other materials.

One advantage is that the graphite material is relatively lightweight as compared to silicon, aluminum, copper, diamond and other materials traditionally used. Such relatively small lightweight high capacity microchannel heat sink members are particularly useful in relatively small computing devices such as laptop computers, personal digital assistants, and cell phones. Each of the flexible graphite sheets from which the heat sink members 300 are constructed preferably has a density in the range of from about 1.0 g/cc to about 2.0 g/cc. More preferably the sheets have a density in the range of from about 1.4 g/cc to about 2.0 g/cc. The thermal conductivity of the sheet is preferably at least about 140 W/m° K., more preferably at least about 400 W/m° K.

Another advantage of the heat sink members formed from graphite materials is that the material is inert to water which is the most common cooling liquid utilized with microchannel heat sinks. This is in contrast to some of the other materials such as aluminum which have been used for microchannel heat sinks. Although the preferred cooling medium utilized with microchannel heat sinks made from graphite materials is water, any other suitable coolant fluid can be utilized, so long as it does not include solvents or the like which would attack the resin in the flexible graphite sheet.

Another advantage of the microchannel heat sinks made from graphite materials is that the material itself has a good thermal conductivity as contrasted to some of the other materials such as silicon which have been used for microchannel heat sinks.

Another advantage of microchannel heat sinks made with graphite materials is that the graphite material has a comparable coefficient of thermal expansion to semiconductor and ceramic materials conventionally used for microprocessors and other electronic devices.

Another advantage of the microchannel heat sink members 300 made from graphite materials is that the microchannels can be formed into the material using high volume manufacturing methods such as roller embossing which allows a cost effective manufacture of the material. Channels down to approximately 100 microns in width can be produced by roller embossing.

Where resin impregnated graphite sheets are utilized, the graphite sheets preferably have a resin content of at least 5% by weight. More preferably they have a resin content in the range of from about 10% by weight to about 35% by weight. Suitably the resin content can be up to about 60% by weight.

Many other methods can be utilized to form the microchannels in the sheets of flexible graphite material. Other methods can include machining, etching such as acid etching, air scribing, sonic machining, laser ablation, stamping, photolithography, and the like.

A method of manufacturing a microchannel heat sink 300A can be generally described as including the following steps:

(a) providing a first sheet 302A of graphite material having two major surfaces 303A and 305A;

(b) forming a plurality of microchannels 314A in one of the major surfaces 303A of the first sheet 302A;

(c) superimposing a second sheet 304A upon the first sheet 302A and joining adjacent major surfaces 303A and 309A of the first and second sheets together to close a cross-section of the microchannels 314A; and

(d) providing a thermal contact surface 308A on an exposed major surface such as 306A of the second sheet 304A for mounting of an electronic device 312.

In an alternative embodiment any of the microchannel heat sink members 300A-300F can be utilized simply as a heat transfer member by filling the microchannel with liquid such as water and closing the ends thereof In this embodiment the fluid does not flow through the microchannels, but the presence of the fluid in the microchannel provides a heat transfer medium which causes the microchannel heat sink to serve as a very effective heat pipe or heat transfer member.

FIG. 11a,b are photomicrographs taken of a cross-section of a flexible graphite sheet such as 302A having microchannels formed by embossing in one and two major surfaces respectively thereof. The photographs of FIG. 11 have a scale of 0.25 mm. The flexible graphite sheet has a thickness of about 0.9 mm to about 1.2 mm. The microchannels formed therein have a depth of 0.4-0.5 mm and a width of 0.6-1.0 mm.

The ability to emboss microchannels in graphite versus the more costly machining or acid etching required for silicon materials provides still another advantage of the present invention, along with the light weight of the graphite microchannel heat sink.

Although this application is written in terms of the application of microchannel heat sinks for cooling electronic devices such as microprocessors, it will be recognized that the inventive method and heat sink are equally applicable to other heat sources.

All cited patents and publications referred to in this application are incorporated by reference.

The invention thus being described, it will obvious that it may be varied in many ways. Such variations are not to be regarded as a departure from the spirit and scope of the present invention and all such modifications as would be obvious to one skilled in the art are intended to be included in the scope of the following claims.

What is claimed is:

1. An apparatus for cooling an electronic device, comprising:
a heat sink member having at least a first thermal contact surface for making thermal contact with said electronic device;
said member being constructed of at least a first sheet of compressed particles of exfoliated graphite, said sheet having two major surfaces; and
at least one of said major surfaces having a first plurality of microchannels formed therein for carrying coolant fluid, said microchannels each having a length parallel to said one of said major surfaces and having a cross-section normal to said length, said cross-section having at least one dimension below about 1,000 microns.

2. The apparatus of claim 1, wherein:
said member includes a second sheet of compressed particles of exfoliated graphite, said first and second sheets being joined together to define said cross-section of said microchannels.

3. The apparatus of claim 2, wherein said second sheet is a flat sheet without microchannels and defines a cap on the microchannels of the first sheet.

4. The apparatus of claim 2, wherein said second sheet has a plurality of microchannels defined therein in a pattern complementary to and superimposed upon the microchannels of the first sheet.

5. The apparatus of claim 2, wherein:
said first thermal contact surface is defined on the major surface of said first sheet opposite said microchannels; and
said second sheet has a second thermal contact surface for making thermal contact with a second electronic device, so that said heat sink member may be interposed between two stacked electronic devices.

6. The apparatus of claim 2, wherein:
said member includes a third sheet of compressed particles of exfoliated graphite, said third sheet being joined to one of said first and second sheets; and
said third sheet and said one of said first and second sheets having a second plurality of microchannels defined therebetween and isolated from said first plurality of microchannels, so that said first and second pluralities of microchannels may carry coolant fluid in opposite directions.

7. The apparatus of claim 6, wherein:
said member includes a second thermal contact surface on a side thereof opposite said first thermal contact surface.

8. The apparatus of claim 7, in combination with first and second stacked electronic devices, said first and second electronic devices being mounted on said first and second thermal contact surfaces, respectively.

9. The apparatus of claim 1, wherein:
said at least one dimension of said cross-section is at least about 100 microns.

10. The apparatus of claim 1, wherein:
said first sheet has a density in the range of from about 1.0 g/cc to about 2.0 g/cc.

11. The apparatus of claim 1, wherein:
said first sheet has a thickness in a range of from about 0.4 mm to about 3.75 mm.

12. The apparatus of claim 12, wherein:
said first sheet has a thickness of no greater than about 2.0 mm.

13. The apparatus of claim 12, wherein:
said first sheet has a thickness of no greater than about 1.0 mm.

14. The apparatus of claim 1, wherein:
said first sheet is resin impregnated and has a resin content of at least about 5% by weight.

15. The apparatus of claim 1, further comprising:
a thermal interface formed from a sheet of anisotropic flexible graphite material attached to said heat sink member and defining said first thermal contact surface.

16. The apparatus of claim 1, in combination with said electronic device, said electronic device being mounted on said first thermal contact surface.

17. The apparatus of claim 1, wherein said microchannels are formed in said first sheet by roller embossing.

18. The apparatus of claim 1, wherein said at least one dimension below about 1,000 microns includes a width of said cross section.

19. A liquid cooled electronic apparatus, comprising:
first and second stacked electronic devices operable under conditions of high heat flux density;
a heat sink member interposed between, and in thermal contact with each of said first and second stacked electronic devices; and
said member being constructed of at least two sheets of flexible graphite material having major surfaces thereof joined together, at least one of said sheets having a plurality of microchannels formed therein for carrying coolant liquid.

20. A method of manufacturing a microchannel heat sink from graphite materials, comprising:
(a) providing first and second sheets of flexible graphite material, each sheet having two major surfaces;
(b) forming a plurality of microchannels in at least one of said major surfaces of said first sheet;
(c) superimposing said second sheet upon said first sheet and joining adjacent major surfaces of said first and second sheets together to close a cross-section of said microchannels; and
(d) providing a thermal contact surface on an exposed major surface of one of said first and second sheets for mounting of an electronic device.
